(19) United States
(12) Patent Application Publication
(10) Pub. No.: US 2019/0203160 A1
(43) Pub. Date: Jul. 4, 2019

(54) CLEANING COMPOSITION AND CLEANING METHOD OF ELECTRONIC COMPONENT USING THE SAME

(71) Applicant: SAMSUNG ELECTRO-MECHANICS CO., LTD., Suwon-Si (KR)

(72) Inventors: Sang Hyun KWON, Suwon-Si (KR); Jin Hee HWANG, Suwon-Si (KR); Young Ju LEE, Suwon-Si (KR); Seong Chan PARK, Suwon-Si (KR)

(21) Appl. No.: 16/053,257

(22) Filed: Aug. 2, 2018

(30) Foreign Application Priority Data
Jan. 4, 2018 (KR) 10-2018-0001292

(51) Int. Cl. C11D 7/04; C11D 7/32; C11D 7/26; C11D 11/00; H01L 21/02; B08B 3/08

(52) U.S. Cl. CPC C11D 7/04; C11D 7/3209; C11D 7/265; B08B 3/08; C11D 11/0047; H01L 21/02068; C11D 7/3218

(57) ABSTRACT

A cleaning composition contains: 0.5 to 5 wt % of an acid; 1 to 20 wt % of an amine-based compound; 0.2 to 5 wt % of a corrosion inhibitor including a silane-based compound; and a balance of pure water. A cleaning composition contains: 1 to 10 wt % of a quaternary alkyl ammonium compound; 0.5 to 5 wt % of a corrosion inhibitor including at least one selected from the group consisting of a silane-based compound, an ammonium nitrate compound, and an ammonium phosphate compound; and a balance of pure water.

### CROSS-REFERENCE TO RELATED APPLICATION(S)

This application claims the benefit of priority to Korean Patent Application No. 10-2018-0001292, filed on Jan. 4, 2018 in the Korean Intellectual Property Office, the disclosure of which is incorporated herein by reference in its entirety.

### BACKGROUND

### 1. Field

The present disclosure relates to a cleaning composition used to remove a specific particle, a metal oxide layer, or the like, from a component in a cleaning process of an electronic component.

### 2. Description of Related Art

A cleaning solution is used to remove a specific particle, a metal oxide layer, or the like, from a component in a cleaning process in a manufacturing process of an electronic component such as a semiconductor or a liquid crystal display (LCD) panel. For example, a metal oxide layer such as Al₂O₃ may be formed on an aluminum (Al) pad of a die for an integrated circuit (IC), and thus, a cleaning solution suitable for removing the oxide layer is required for a packaging process corresponding to a subsequent process.

Meanwhile, the oxide layer is generally removed by a wetting cleaning method using a strong acid or alkaline cleaning solution. However, when a pad or microcircuit of an electronic component, formed of a metal such as aluminum (Al) is exposed to a strong acid or alkaline cleaning solution described above, fatal damage such as corrosion or etching may occur.

### SUMMARY

An aspect of the present disclosure may provide a cleaning composition capable of effectively removing a particle or metal oxide layer while selectively protecting a metal wiring or metal pad formed of aluminum, or the like, and a cleaning method of an electronic component using the same.

One of several solutions suggested in the present disclosure is to suitably add a corrosion inhibitor including a silane-based compound to an acid and an amine-based compound, or to suitably add and use a corrosion inhibitor including a silane-based compound and/or an ammonium nitrate compound and/or an ammonium phosphate compound to a quaternary alkyl ammonium compound.

According to an aspect of the present disclosure, a cleaning composition may contain: 0.5 to 5 wt % of an acid, based on a total weight of the cleaning composition; 1 to 20 wt % of an amine-based compound, based on the total weight of the cleaning composition; and 0.2 to 5 wt % of a corrosion inhibitor including a silane-based compound, based on the total weight of the cleaning composition.

According to another aspect of the present disclosure, a cleaning composition may contain: 1 to 10 wt % of a quaternary alkyl ammonium compound, based on a total weight of the cleaning composition; and 0.5 to 5 wt % of a corrosion inhibitor including at least one selected from the group consisting of a silane-based compound, an ammonium nitrate compound, and an ammonium phosphate compound, based on the total weight of the cleaning composition.

According to another aspect of the present disclosure, a cleaning method of an electronic component may include: preparing an electronic component having an active surface on which a connection pad is disposed and an inactive surface opposite to the active surface; and cleaning a surface of the connection pad, wherein the cleaning composition described above is used in the cleaning of the surface of the connection pad.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on a ball grid array (BGA) substrate and is ultimately mounted on a mainboard of an electronic device;

FIG. 6 is a schematic cross-sectional view illustrating a case in which a fan-in semiconductor package is embedded in a ball grid array (BGA) substrate and is ultimately mounted on a mainboard of an electronic device;

FIG. 7 is a schematic cross-sectional view illustrating a fan-out semiconductor package; and

FIG. 8 is a schematic cross-sectional view illustrating a case in which a fan-out semiconductor package is mounted on a mainboard of an electronic device.

### DETAILED DESCRIPTION

Hereinafter, exemplary embodiments in present disclosure will be described with reference to the accompanying drawings. In the accompanying drawings, shapes, sizes, and the like, of components may be exaggerated or shortened for clarity.

Electronic Device

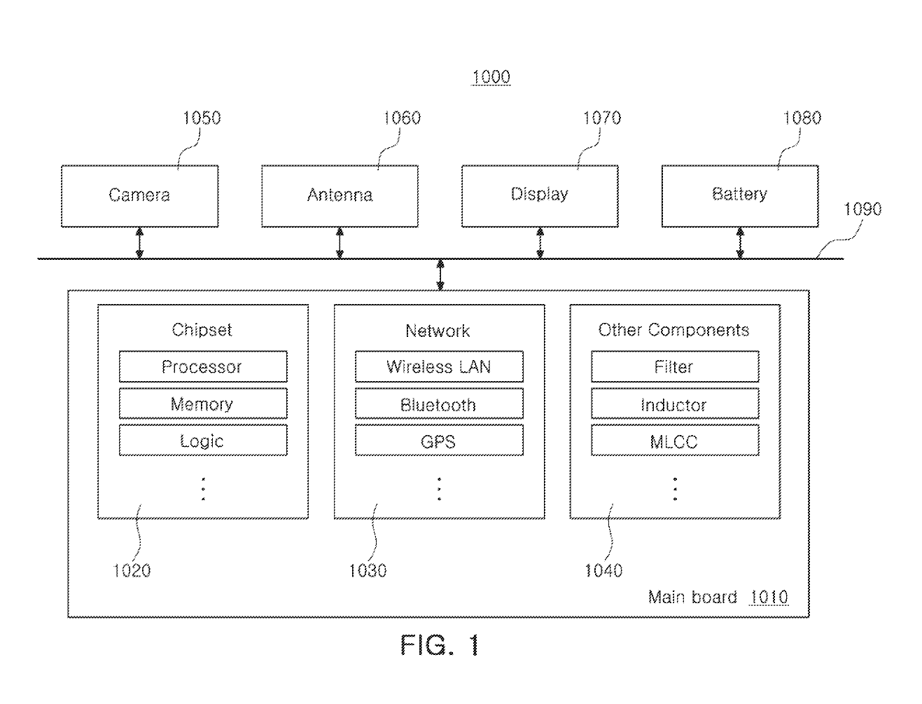

FIG. 1 is a block diagram schematically illustrating an example of an electronic device system.

Referring to FIG. 1, an electronic device 1000 may accommodate a main board 1010 therein. The main board 1010 may include chip-related components 1020, network-related components 1030, other components 1040, and the like, physically or electrically connected thereto. These components may be connected to others to be described below to form various signal lines 1090.

The chip-related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip-related components 1020 are not limited thereto, but may also include other types of chip related components. In addition, the chip-related components 1020 may be combined with each other.

The network-related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network-related components 1030 are not limited thereto, but may also include a variety of other wireless or wired standards or protocols. In addition, the network-related components 1030 may be combined with each other, together with the chip-related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip-related components 1020 or the network-related components 1030 described above.

Depending on a type of the electronic device 1000, the electronic device 1000 may include other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

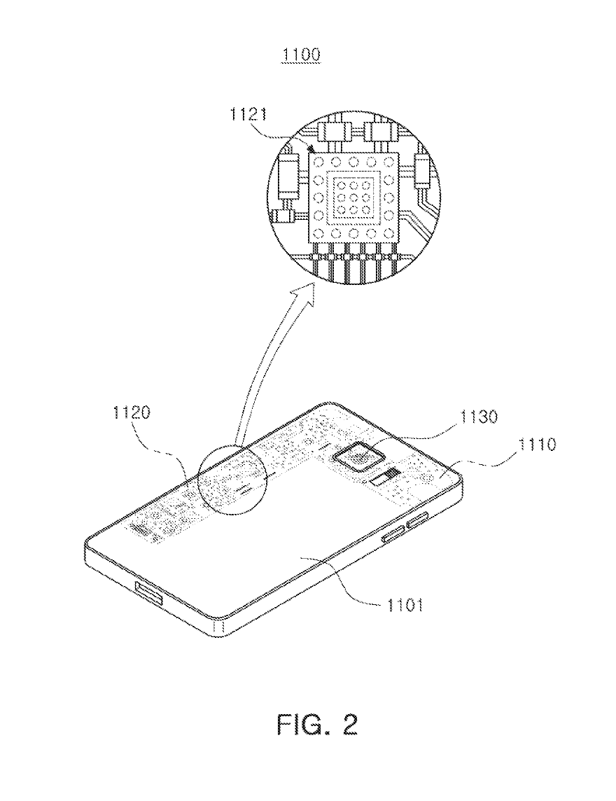

FIG. 2 is a schematic perspective view illustrating an example of an electronic device.

Referring to FIG. 2, a semiconductor package may be used for various purposes in the various electronic devices 1000 as described above. For example, a motherboard 1110 may be accommodated in a body 1101 of a smartphone 1100, and various electronic components 1120 may be physically or electrically connected to the motherboard 1110. In addition, other components that may or may not be physically or electrically connected to the main board 1010, such as a camera module 1130, may be accommodated in the body 1101. Some of the electronic components 1120 may be the chip related components, for example, a semiconductor package 1121, but are not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-In Semiconductor Package

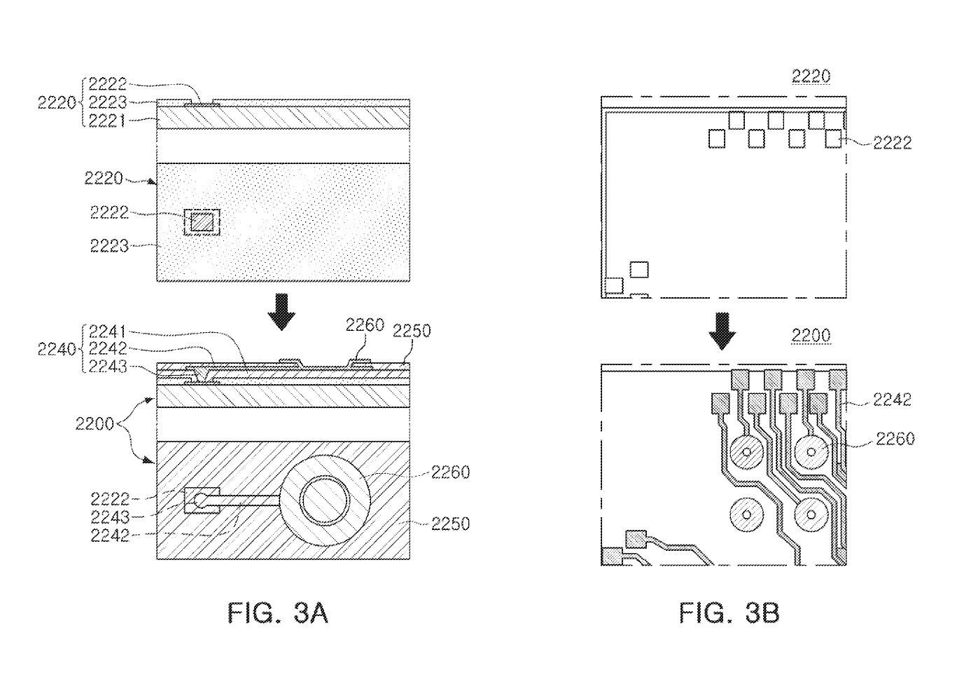

FIGS. 3A and 3B are schematic cross-sectional views illustrating states of a fan-in semiconductor package before and after being packaged.

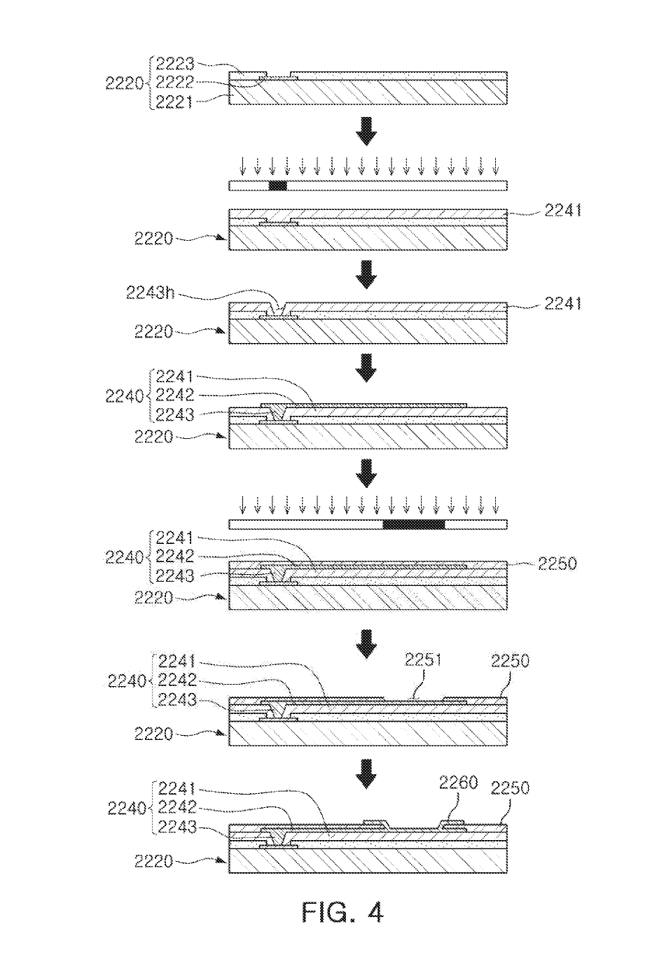

FIG. 4 is schematic cross-sectional views illustrating a packaging process of a fan-in semiconductor package.

Referring to FIGS. 3 and 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide layer, a nitride layer, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even in a case in which a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in electronic component package on the mainboard of the electronic device.

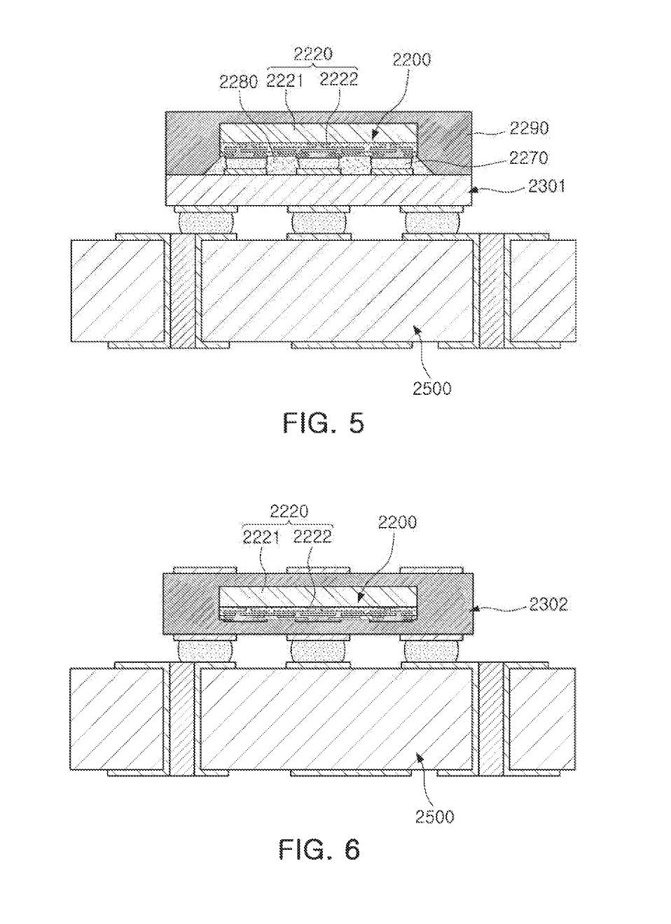

FIG. 5 is a schematic cross-sectional view illustrating a case in which a fan-in semiconductor package is mounted on a ball grid array (BGA) substrate and is ultimately mounted on a mainboard of an electronic device.

FIG. 6 is a schematic cross-sectional view illustrating a case in which a fan-in semiconductor package is embedded in a ball grid array (BGA) substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through a BGA substrate 2301, and the fan-in semiconductor package 2200 may be ultimately mounted on a mainboard 2500 of an electronic device in a state in which it is mounted on the BGA substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate BGA substrate 2302, connection pads 2222, that is, I/O terminals, of the semiconductor chip 2220 may be redistributed by the BGA substrate 2302 in a state in which the fan-in semiconductor package 2200 is embedded in the BGA substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate BGA substrate and be then mounted on the mainboard of the electronic device through a packaging process or may be mounted and used on the mainboard of the electronic device in a state in which it is embedded in the BGA substrate.

Fan-Out Semiconductor Package

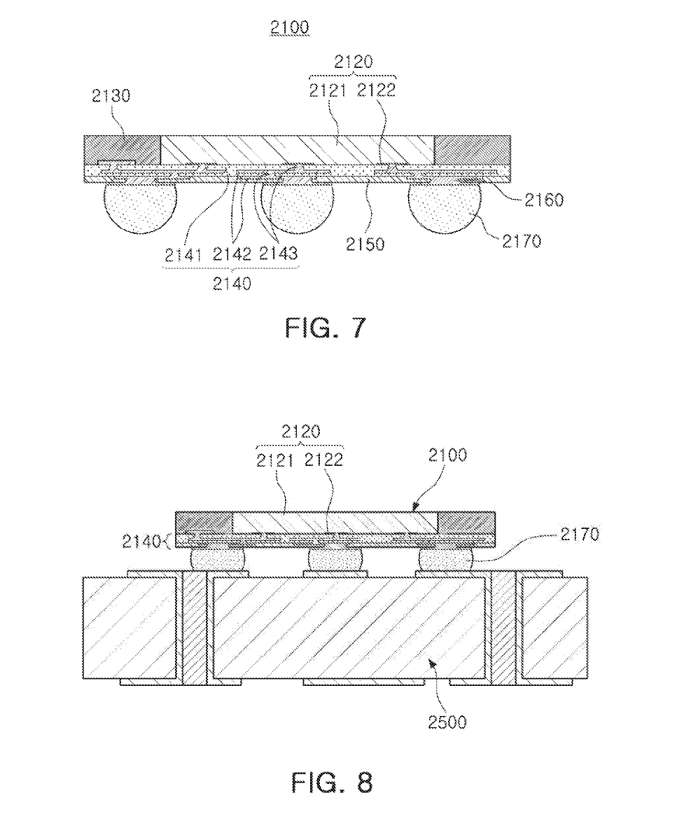

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case that a size of the semiconductor chip is decreased, a standardized ball layout may be used in the fan-out semiconductor package as it is, such that the fan-out semiconductor package may be mounted on the mainboard of the electronic device without using a separate BGA substrate, as described below.

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate BGA substrate, or the like.

As described above, since the fan-out semiconductor package may be mounted on the mainboard of the electronic device without using the separate BGA substrate, the fan-out semiconductor package may be implemented at a thickness lower than that of the fan-in semiconductor package using the BGA substrate. Therefore, the fan-out semiconductor package may be miniaturized and thinned. In addition, the fan-out electronic component package has excellent thermal characteristics and electrical characteristics, such that it is particularly appropriate for a mobile product. Therefore, the fan-out electronic component package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as a BGA substrate, or the like, having a scale, a purpose, and the like, different from those of the fan-out semiconductor package, and having the fan-in semiconductor package embedded therein.

Cleaning Composition

Hereinafter, a cleaning composition capable of being used in a cleaning process in a manufacturing process of the semiconductor package as described above will be described.

### 1. FIRST EXEMPLARY EMBODIMENT

First, a cleaning composition according to an exemplary embodiment may contain 0.5 to 5 wt % of an acid, based on a total weight of the cleaning composition, 1 to 20 wt % of an amine-based compound, based on the total weight of the cleaning composition, 0.2 to 5 wt % of a corrosion inhibitor including a silane-based compound, based on the total weight of the cleaning composition, and a balance of pure water. The balance is pure water, which means that pure water is contained in a residual amount except for the other ingredients, and when another additive, or the like, in addition to the above-mentioned ingredients is further contained, a content of pure water may also be changed in accordance therewith.

As described above, a cleaning solution is used to remove a specific particle, a metal oxide layer, or the like, of a component in a cleaning process in a manufacturing process of an electronic component such as a semiconductor or a liquid crystal display (LCD) panel. For example, a metal oxide layer such as Al₂O₃ is formed on an aluminum (Al) pad of a die for an integrated circuit (IC), and thus, a suitable cleaning solution for removing the oxide layer is required for a packaging process corresponding to a subsequent process. In this case, the oxide layer is generally removed by a wetting cleaning method using a strong acid or alkaline cleaning solution. However, when a pad or microcircuit of an electronic component, formed of a metal such as aluminum (Al) is exposed to a strong acid or alkaline cleaning solution described above, fetal damages such as corrosion or etching may occur.

On the other hand, in the cleaning composition according to the exemplary embodiment, instead of simply using a strong acid or alkaline solution, suitable amounts of acid and amine-based compound may be mixed with each other to thereby be used as a buffer, and a suitable amount of silane-based compound may be further added thereto as the corrosion inhibitor to thereby be used. In this case, as appreciated from experimental results to be described below, the metal wiring or metal pad formed of aluminum (Al), or the like, may be selectively protected, but the particle or metal oxide layer may be effectively removed, thereby making it possible to promote improvement of adhesive force with an insulating layer or plating layer formed on the pad in a subsequent packaging process. Particularly, since suitable amounts of acid and amine-based compound are mixed with each other to thereby be used as the buffer, even though other liquids, for example, pure water is added thereto or another liquid is mixed therewith to contaminate the cleaning composition, there is no change in pH, and the cleaning solution may be used for a long period of time. That is, the cleaning composition according to the exemplary embodiment may be a basic mixed solution having a pH of about 9 to 12, and thus the cleaning composition may have significantly high efficiency in removing a thin film or particles of an inorganic or organic ingredient, existing on a surface of a precision component or a metal for an electronic component, and be used for a long period of time.

Meanwhile, a cleaning composition according to the exemplary embodiment may contain, more preferably 0.5 to 1.5 wt % of the acid, 10 to 15 wt % of the amine-based compound, 0.3 to 1 wt % of the corrosion inhibitor including the silane-based compound, based on the total weight of the cleaning composition, and a balance of pure water. In this case, the above-mentioned effect may be more effectively implemented. If necessary, the cleaning composition may further contain a suitable amount of other additives.

Hereinafter, each ingredient contained in the cleaning composition according to the exemplary embodiment will be described in more detail.

(1-1) Acid

The acid may constitute the buffer together with the amine-based compound, and this buffer may substantially serve as a cleaning solution. The acid may be at least one selected from the group consisting of sulfuric acid, nitric acid, hydrochloric acid, hydrofluoric acid, acetic acid, and nitrous acid, and preferably, acetic acid, but is not limited thereto. The acid may be contained in a content of 0.5 to 5 wt % and more preferably 0.5 to 1.5 wt % in the cleaning composition, based on the total weight of the cleaning composition. When the content of the acid is higher than this range, the pH may be lower than an intended pH, and when the content of the acid is lower than this range, cleaning performance may be rather decreased.

(1-2) Amine-Based Compound

The amine-based compound may constitute the buffer together with the acid, and this buffer may substantially serve as the cleaning solution. The amine-based compound may be at least one selected from the group consisting of an ammonia solution, alkyl amine, dialkyl amine, trialkyl amine, hydroxyalkyl amine, dihydroxyalkyl amine, and trihydroxyalkyl amine, and preferably the ammonia solution, but is not limited thereto. Meanwhile, examples of alkyl amine may include methyl amine, ethyl amine, and the like; examples of dialkyl amine may include dimethyl amine, diethyl amine, methylethyl amine, and the like; examples of trialkyl amine may include trimethyl amine, triethyl amine, methyldiethyl amine, ethyldimethyl amine, and the like; examples of hydroxyalkyl amine may include methanol amine, ethanol amine, and the like; examples of dihydroxyalkyl amine may include dimethanol amine, diethanol amine, hydroxymethylhydroxyethyl amine, and the like; and examples of trihydroxyalkyl amine may include trimethanol amine, triethanol amine, hydroxymethyldihydroxyethyl amine, hydroxyethyldihydroxymethyl amine, and the like, but the examples are not limited thereto. The amine-based compound may be contained in a content of 1 to 20 wt % and more preferably 10 to 15 wt % in the cleaning composition, based on the total weight of the cleaning composition. When the content of the amine-based compound is higher than this range, a metal protection function may be deteriorated due to an increase in attack on a metal such as aluminum (Al), and when the content is lower than this range, cleaning performance may be rather deteriorated.

(1-3) Corrosion Inhibitor

Next, the corrosion inhibitor may serve to protect the metal wiring or metal pad. As the corrosion inhibitor, the silane-based compound may be used. More specifically, at least one selected from the group consisting of compounds represented by the following [Chemical Formula 1] and [Chemical Formula 2] and compounds including a repeating unit represented by the following [Chemical Formula 3] may be used as the corrosion inhibitor. More preferably, at least one selected from the group consisting of compounds represented by the following [Chemical Formula 1] and [Chemical Formula 2] may be used as the corrosion inhibitor, but the corrosion inhibitor is not limited thereto. Meanwhile, in a case of using these compounds, the cleaning composition may have more excellent cleaning performance in addition to a corrosion inhibition effect. A mixture of these compounds may be used.

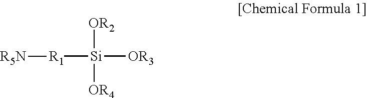

Here, R₁ is a substituted or unsubstituted (C₁-C₁₀) aliphatic chain, R₂ to R₄ are each independently a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof, and R₅ is hydrogen, a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof. For example, the compound represented by [Chemical Formula 1] may be (3-aminopropyl)triethoxysilane, or the like, but is not limited thereto.

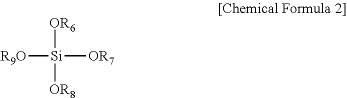

Here, R₆ to R₉ are each independently a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof. For example, the compound represented by [Chemical Formula 2] may be tetraethoxysilane, tetramethoxysilane, or the like, but is not limited thereto.

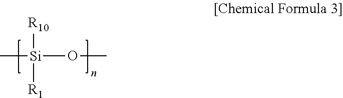

Here, R₁₀ and R₁₁ are each independently hydrogen, a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof, and n is an integer of 1 to 2000. For example, the compound having the repeating unit represented by [Chemical Formula 3] may be polysiloxane, and any polysiloxane may be used as long as it has the above-mentioned repeating unit.

Meanwhile, an aliphatic chain, which means a linear or branched chain aliphatic compound, may be, for example, saturated or unsaturated hydrocarbon, alkoxy, alkyl ester, alkyl ether, thioalkyl, or the like, but is not limited thereto. Here, the aliphatic chain may include at least one substituent in a main chain and/or a side chain, wherein the substituent may be, for example, halogen, oxygen, sulfur, nitrogen, a hydroxyl group, a carboxyl group, an alkyl group, a haloalkyl group, a nitro group, a cyano group, an ester group, an ether group, an amide group, an imide group, an alkoxy group, or a combination thereof, but is not limited thereto.

Further, an aliphatic ring, which means a cyclic aliphatic compound, may be a monocyclic compound or a polycyclic compound formed by condensation of two or more rings, for example, a saturated or unsaturated hydrocarbon ring such as cycloalkyl. The aliphatic ring may include at least one substituent, wherein the substituent may be, for example, halogen, oxygen, sulfur, nitrogen, a hydroxyl group, a carboxyl group, an alkyl group, a haloalkyl group, a nitro group, a cyano group, an ester group, an ether group, an amide group, an imide group, an alkoxy group, or a combination thereof, but is not limited thereto.

In addition, an aromatic ring, which means a cyclic aromatic compound, may be a monocyclic compound or a polycyclic compound formed by condensation of two or more rings. For example, the aromatic ring may be aryl such as phenyl, naphthalene, or the like. The aromatic ring may include at least one substituent, wherein the substituent may be, for example, halogen, oxygen, sulfur, nitrogen, a hydroxyl group, a carboxyl group, an alkyl group, a haloalkyl group, a nitro group, a cyano group, an ester group, an ether group, an amide group, an imide group, an alkoxy group, or a combination thereof, but is not limited thereto.

Meanwhile, the corrosion inhibitor, for example, the silane-based compound may be contained in a content of 0.2 to 5 wt % and more preferably 0.3 to 1 wt % in the cleaning composition. When the content of the corrosion inhibitor, for example, the silane-based compound is lower than this range, the corrosion inhibition effect may be insufficient, and when the content is higher than this range, the corrosion inhibitor may be precipitated, such that the corrosion inhibitor may not be removed at the time of rinsing.

(1-4) pH

The cleaning composition according to the exemplary embodiment may have a pH of 9 to 12, more preferably about 10 to 11. When the pH of the cleaning composition is within the above-mentioned range, cleaning performance may be excellent. When the pH is larger than this range, the metal protection function may be deteriorated due to an increase in attack on the metal such as aluminum (Al).

### 2. SECOND EXEMPLARY EMBODIMENT

Next, a cleaning composition according to another exemplary embodiment may contain 1 to 10 wt % of a quaternary alkyl ammonium compound, based on a total weight of the cleaning composition, 0.5 to 5 wt % of a corrosion inhibitor including at least one selected from the group consisting of a silane-based compound, an ammonium nitrate compound, based on the total weight of the cleaning composition, and an ammonium phosphate compound, and a balance of pure water. More specifically, the cleaning composition may contain 1 to 10 wt % of the quaternary alkyl ammonium compound, based on the total weight of the cleaning composition, 0.1 to 1 wt % of the silane-based compound and 0.4 to 4 wt % of the ammonium nitrate compound or the ammonium phosphate compound as the corrosion inhibitors, based on the total weight of the cleaning composition, and a balance of pure water. Alternatively, the cleaning composition may contain 1 to 10 wt % of the quaternary alkyl ammonium compound, based on the total weight of the cleaning composition, 0.5 to 5 wt % of the ammonium nitrate compound or the ammonium phosphate compound as the corrosion inhibitor, based on the total weight of the cleaning composition, and a balance of pure water. The balance is pure water, which means that pure water is contained in a residual amount except for the other ingredients, and when another additive, or the like, in addition to the above-mentioned ingredients is further contained, a content of pure water may also be changed in accordance therewith.

Similarly, in the cleaning composition according to another exemplary embodiment, instead of simply using a strong acid or alkaline solution, a suitable amount of the quaternary alkyl ammonium compound may be used, and a suitable amount of a corrosion inhibitor having a specific combination may be further added thereto to thereby be used. In this case, as appreciated from experimental results to be described below, the metal wiring or metal pad formed of aluminum (Al), or the like, may be selectively protected, but the particle or metal oxide layer may be effectively removed, thereby making it possible to promote improvement of adhesive force with an insulating layer or plating layer formed on the pad in a subsequent packaging process and prevention of corrosion of the pad. Further, the cleaning composition according to another exemplary embodiment may also be a basic mixed solution having a pH of about 9 to 12, and thus the cleaning composition may have significantly high efficiency in removing a thin film or particles of an inorganic or organic ingredient, existing on a surface of a precision component or a metal for an electronic component, and be used for a long period of time.

Meanwhile, more preferably, the cleaning composition according to another exemplary embodiment may contain 1 to 5 wt % of the quaternary alkyl ammonium compound, based on the total weight of the cleaning composition, 0.3 to 1 wt % of the silane-based compound and 1 to 2 wt % of the ammonium nitrate compound as the corrosion inhibitors, based on the total weight of the cleaning composition, and a balance of pure water, or contain 1 to 5 wt % of the quaternary alkyl ammonium compound, based on the total weight of the cleaning composition, 3 to 5 wt % of the ammonium nitrate compound as the corrosion inhibitor, based on the total weight of the cleaning composition, and a balance of pure water. In this case, the above-mentioned effect may be more effectively implemented. If necessary, the cleaning composition may further contain 0.5 to 1.5 wt % of an acid, based on the total weight of the cleaning composition, and suitable amounts of other additives.

Hereinafter, each ingredient contained in the cleaning composition according to another exemplary embodiment will be described in more detail.

(2-1) Quaternary Alkyl Ammonium Compound

The quaternary alkyl ammonium compound may substantially serve as a cleaning solution. The quaternary alkyl ammonium compound may be, for example, tetraalkyl ammonium hydroxide. A more specifically, the quaternary alkyl ammonium compound may be at least one selected from tetramethyl ammonium hydroxide, tetraethyl ammonium hydroxide, tetrapropyl ammonium hydroxide, trimethylethyl ammonium hydroxide, ethyltrimethyl ammonium hydroxide, (2-hydroxyethyl)trimethyl ammonium hydroxide, (2-hydroxyethyl)triethyl ammonium hydroxide, (2-hydroxyethyl)tripropyl ammonium hydroxide, and (1-hydroxypropyl)trimethyl ammonium hydroxide, or a mixture thereof, but is not limited thereto. The quaternary alkyl ammonium compound may be contained in a content of 1 to 10 wt % and more preferably 1 to 5 wt % in the cleaning composition, based on the total weight of the cleaning composition. When the content of the quaternary alkyl ammonium compound is higher than this range, a metal protection function may be deteriorated due to an increase in attack on a metal such as aluminum (Al), and when the content is lower than this range, cleaning performance may be rather deteriorated.

(2-2) Corrosion Inhibitor

Next, the corrosion inhibitor may serve to protect the metal wiring or metal pad. As the corrosion inhibitor, at least one selected from the group consisting of the silane-based compound, the ammonium nitrate compound, and the ammonium phosphate compound may be used. More specifically, a mixture of the silane-based compound and the ammonium nitrate compound may be used, a mixture of the silane-based compound and the ammonium phosphate compound may be used, the ammonium nitrate compound may be used alone, or the ammonium phosphate compound may be used alone.

Meanwhile, as the silane-based compound, at least one selected from the group consisting of compounds represented by the following [Chemical Formula 1] and [Chemical Formula 2] and compounds including a repeating unit represented by the following [Chemical Formula 3] may be used as the corrosion inhibitor. More preferably, at least one selected from the group consisting of compounds represented by the following [Chemical Formula 1] and [Chemical Formula 2] may be used as the corrosion inhibitor, but the corrosion inhibitor is not limited thereto. Meanwhile, in a case of using these compounds, the cleaning composition may have more excellent cleaning performance in addition to a corrosion inhibition effect. A mixture of these compounds may be used.

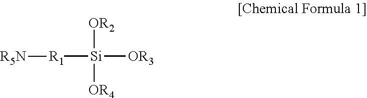

Here, R₁ is a substituted or unsubstituted (C₁-C₁₀) aliphatic chain, R₂ to R₄ are each independently a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof, and R₅ is hydrogen, a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof. For example, the compound represented by [Chemical Formula 1] may be (3-aminopropyl)triethoxysilane, or the like, but is not limited thereto.

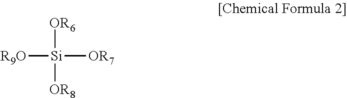

Here, R₆ to R₉ are each independently a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof. For example, the compound represented by [Chemical Formula 2] may be tetraethoxysilane, tetramethoxysilane, or the like, but is not limited thereto.

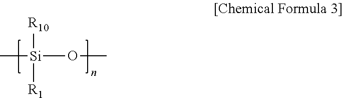

Here, R₁₀ and R₁₁ are each independently hydrogen, a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof, and n is an integer of 1 to 2000. For example, the compound having the repeating unit represented by [Chemical Formula 3] may be polysiloxane, and any polysiloxane may be used as long as it has the above-mentioned repeating unit.

Meanwhile, an aliphatic chain, which means a linear or branched chain aliphatic compound, may be, for example, saturated or unsaturated hydrocarbon, alkoxy, alkyl ester, alkyl ether, thioalkyl, or the like, but is not limited thereto. Here, the aliphatic chain may include at least one substituent in a main chain and/or a side chain, wherein the substituent may be, for example, halogen, oxygen, sulfur, nitrogen, a hydroxyl group, a carboxyl group, an alkyl group, a haloalkyl group, a nitro group, a cyano group, an ester group, an ether group, an amide group, an imide group, an alkoxy group, or a combination thereof, but is not limited thereto.

Further, an aliphatic ring, which means a cyclic aliphatic compound, may be a monocyclic compound or a polycyclic compound formed by condensation of two or more rings, for example, a saturated or unsaturated hydrocarbon ring such as cycloalkyl. The aliphatic ring may include at least one substituent, wherein the substituent may be, for example, halogen, oxygen, sulfur, nitrogen, a hydroxyl group, a carboxyl group, an alkyl group, a haloalkyl group, a nitro group, a cyano group, an ester group, an ether group, an amide group, an imide group, an alkoxy group, or a combination thereof, but is not limited thereto.

In addition, an aromatic ring, which means a cyclic aromatic compound, may be a monocyclic compound or a polycyclic compound formed by condensation of two or more rings. For example, the aromatic ring may be aryl such as phenyl, naphthalene, or the like. The aromatic ring may include at least one substituent, wherein the substituent may be, for example, halogen, oxygen, sulfur, nitrogen, a hydroxyl group, a carboxyl group, an alkyl group, a haloalkyl group, a nitro group, a cyano group, an ester group, an ether group, an amide group, an imide group, an alkoxy group, or a combination thereof, but is not limited thereto.

Further, the ammonium nitrate compound may be ammonium nitrate, and the ammonium phosphate compound may be ammonium phosphate.

Meanwhile, in a case of using the mixture of the silane-based compound and the ammonium nitrate compound or the mixture of the silane-based compound and the ammonium phosphate compound as the corrosion inhibitor, the cleaning composition may contain 0.1 to 1 wt % of the silane-based compound and 0.4 to 4 wt % of the ammonium nitrate compound or the ammonium phosphate compound, more preferably, 0.3 to 1 wt % of the silane-based compound and 1 to 2 wt % of the ammonium nitrate compound or the ammonium phosphate compound, based on the total weight of the cleaning composition. Further, in a case of using the ammonium nitrate compound or the ammonium phosphate compound alone as the corrosion inhibitor, the cleaning composition may contain 0.5 to 5 wt % of the ammonium nitrate compound or the ammonium phosphate compound and more preferably 3 to 5 wt % of the ammonium nitrate compound or the ammonium phosphate compound, based on the total weight of the cleaning composition. When the content of the corrosion inhibitor is lower than this range, the corrosion inhibition effect may be insufficient, and when the content is higher than this range, the corrosion inhibitor may be precipitated, such that the corrosion inhibitor may not be removed at the time of rinsing.

(2-3) Acid

The acid may be mixed with the quaternary alkyl ammonium compound, thereby providing a buffer. The acid may be at least one selected from the group consisting of sulfuric acid, nitric acid, hydrochloric acid, hydrofluoric acid, acetic acid, and nitrous acid, and preferably, acetic acid, but is not limited thereto. The acid may be contained in a content of 0.5 to 1.5 wt % in the cleaning composition, based on the total weight of the cleaning composition. When the content of the acid is higher than this range, the pH may be lower than an intended pH, and when the content of the acid is lower than this range, cleaning performance may be rather decreased.

(2-4) pH

The cleaning composition according to another exemplary embodiment may have a pH of 9 to 12, more preferably about 10 to 11. In this case, cleaning performance may be excellent. When the pH is larger than this range, the metal protection function may be deteriorated due to an increase in attack on the metal such as aluminum (Al).

### 3. EXPERIMENTAL EXAMPLE

First, a cleaning composition was prepared using ingredients having a content illustrated in the following [Table 1] and a balance of pure water.

TABLE 1

| | Comparative | | Experimental |
|---|---|---|---|
| | Experimental | Experimental | Example |
| Classification | Example | Example 1 | 2 |
| Acid | — | Acetic Acid 1% | — |
| Base | Tetra-methyl | Ammonia | Tetra-methyl |
| | ammonium | Solution | ammonium hydroxide |
| | hydroxide 3% | 12% | 3% |
| Corrosion | — | Amino-propyl- | Amino-propyl- |
| Inhibitor | | triethoxysilane | triethoxysilane 0.5% |
| | | 0.4% | Ammonium Nitrate |
| | | | 1.5% |

A metal etch rate and oxide cleaning performance were measured using each of the prepared cleaning compositions, and the results are illustrated in the following [Table 2] Meanwhile, the metal etch rate was measured by treating an aluminum (Al) film with each of the compositions at room temperature for 2 minutes and measuring thicknesses of the aluminum (Al) film before and after treatment using a 4-point probe. Further, oxide cleaning performance was measured using X-ray photoelectron spectroscopy (XPS). When the aluminum (Al) film was not cleaned, 20% or more of oxide was detected on the aluminum (Al) film.

TABLE 2

| | | Al Etch Rate | Oxide Cleaning | Al |
|---|---|---|---|---|
| | pH | (nm/min) | Performance | Attack |
| Comparative | 13.6 | 60~80 | <2% | NG |
| Experimental | | | | |
| Example | | | | |
| Experimental | 10.58 | 1.4 | <2% | OK |
| Example 1 | | | | |
| Experimental | 10.56 | 0.9 | <2% | OK |
| Example 2 | | | | |

As illustrated in experimental results in [Table 2], it may be appreciated that in Experimental Examples 1 and 2, an aluminum etch rate was significantly low as compared to Comparative Experimental Example, but cleaning performance was equivalent to that in Comparative Experimental Example. That is, it may be appreciated that the cleaning composition according to the present disclosure may effectively clean the oxide without an attack on aluminum.

As described above, in a case of using the cleaning composition according to the present disclosure, the cleaning composition may selectively protect a metal layer and selectively remove a metal oxide layer or oxide particles in a cleaning process of a precision component, thereby serving to improve adhesive force with an insulating layer or plating layer formed on a pad, or the like, in a subsequent packaging process or to prevent corrosion of the pad. Further, in a case of using the buffer of the acid and the base according to the present disclosure, even though other liquids, for example, pure water is added or another liquid is mixed therewith to contaminate the cleaning composition, there is no change in pH, and the cleaning solution may be used for a long period of time. That is, the cleaning composition may having significantly high efficiency in removing a thin film or particles of an inorganic or organic ingredient, existing on a surface of a precision component for an electronic component or a metal and be used for a long period of time by using the mixed solution of which a hydrogen ion concentration (pH) is basic.

Therefore, the cleaning composition according to the present disclosure described above may be easily used to manufacture the above-mentioned semiconductor package. For example, the cleaning composition may be easily used to clean the connection pad 2222 before forming the connection member 2240 in manufacturing the above-mentioned fan-in semiconductor package of FIGS. 3 and 4. Further, the cleaning composition may be easily used to clean the connection pad 2122 before forming the connection member 2140 in manufacturing the above-mentioned fan-out semiconductor package of FIG. 7. As described above, in a cleaning method of an electronic component including: preparing an electronic component having an active surface on which a connection pad is disposed and an inactive surface opposite to the active surface; and cleaning the connection pad of the electronic component, the cleaning composition according to the present disclosure may be easily used as a cleaning solution in the cleaning of the connection pad of the electronic component.

As set forth above, according to exemplary embodiments in the present disclosure, the cleaning composition capable of effectively removing the particle or metal oxide layer while selectively protecting the metal wiring or metal pad formed of aluminum (Al), or the like, and the cleaning method of an electronic component using the same may be provided.

Herein, a lower side, a lower portion, a lower surface, and the like, are used to refer to a direction toward a mounting surface of the fan-out semiconductor package in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an adhesive layer as well as a direct connection between two components. In addition, “electrically connected” conceptually includes a physical connection and a physical disconnection. It can be understood that when an element is referred to with terms such as “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term “an exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part one with one another. For example, one element described in a particular exemplary embodiment, even if it is not described in another exemplary embodiment, may be understood as a description related to another exemplary embodiment, unless an opposite or contradictory description is provided therein.

Terms used herein are used only in order to describe an exemplary embodiment rather than limiting the present disclosure. In this case, singular forms include plural forms unless interpreted otherwise in context.

While exemplary embodiments have been shown and described above, it will be apparent to those skilled in the art that modifications and variations could be made without departing from the scope of the present invention as defined by the appended claims.

What is claimed is:

1. A cleaning composition comprising:
0.5 to 5 wt % of an acid, based on a total weight of the cleaning composition;
1 to 20 wt % of an amine-based compound, based on the total weight of the cleaning composition;
0.2 to 5 wt % of a corrosion inhibitor including a silane-based compound, based on the total weight of the cleaning composition; and
a balance of pure water.

2. The cleaning composition of claim 1, wherein the acid is at least one selected from the group consisting of sulfuric acid, nitric acid, hydrochloric acid, hydrofluoric acid, acetic acid, and nitrous acid.

3. The cleaning composition of claim 2, wherein the acid is acetic acid, and the content of the acid is 0.5 to 1.5 wt %, based on the total weight of the cleaning composition.

4. The cleaning composition of claim 1, wherein the amine-based compound is at least one selected from the group consisting of an ammonia solution, alkyl amine, dialkyl amine, trialkyl amine, hydroxyalkyl amine, dihydroxyalkyl amine, and trihydroxyalkyl amine.

5. The cleaning composition of claim 4, wherein the amine-based compound is the ammonia solution, and the content of the amine-based compound is 10 to 15 wt %, based on the total weight of the cleaning composition.

6. The cleaning composition of claim 1, wherein the silane-based compound is at least one selected from the group consisting of compounds represented by the following [Chemical Formula 1] and [Chemical Formula 2] and compounds including a repeating unit represented by the following [Chemical Formula 3]: 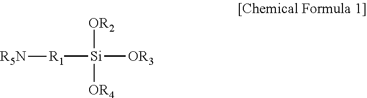
where R₁ is a substituted or unsubstituted (C₁-C₁₀) aliphatic chain,
R₂ to R₄ are each independently a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof, and
R₅ is hydrogen, a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof, 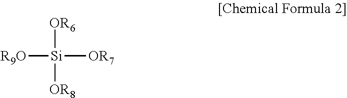
where R₆ to R₉ are each independently a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof, and 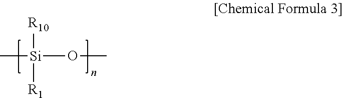
where R₁₀ and R₁₁ are each independently hydrogen, a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof; and
n is an integer of 1 to 2000.

7. The cleaning composition of claim 6, wherein the silane-based compound is at least one selected from the group consisting of the compounds represented by [Chemical Formula 1] and [Chemical Formula 2], and a content of the silane-based compound is 0.3 to 1 wt %, based on the total weight of the cleaning composition.

8. The cleaning composition of claim 1, wherein the cleaning composition has a pH of 9 to 12.

9. A cleaning composition comprising:
1 to 10 wt % of a quaternary alkyl ammonium compound, based on a total weight of the cleaning composition;
0.5 to 5 wt % of a corrosion inhibitor including at least one selected from the group consisting of a silane-based compound, an ammonium nitrate compound, and an ammonium phosphate compound, based on the total weight of the cleaning composition; and
a balance of pure water.

10. The cleaning composition of claim 9, wherein a content of the silane-based compound is 0.1 to 1 wt %, based on the total weight of the cleaning composition, and a content of the ammonium nitrate compound or the ammonium phosphate compound is 0.4 to 4 wt %, based on the total weight of the cleaning composition.

11. The cleaning composition of claim 9, wherein a content of the ammonium nitrate compound or the ammonium phosphate compound is 0.5 to 5 wt %, based on the total weight of the cleaning composition.

12. The cleaning composition of claim 9, wherein the quaternary alkyl ammonium compound includes tetraalkyl ammonium hydroxide, and a content of the quaternary alkyl ammonium compound is 1 to 5 wt %, based on the total weight of the cleaning composition.

13. The cleaning composition of claim 9, wherein the silane-based compound is at least one selected from the group consisting of compounds represented by the following [Chemical Formula 1] and [Chemical Formula 2] and compounds including a repeating unit represented by the following [Chemical Formula 3], and
a content of the silane-based compound is 0.3 to 1 wt %, based on the total weight of the cleaning composition, and a content of the ammonium nitrate compound is 1 to 2 wt %, based on the total weight of the cleaning composition: 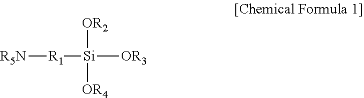
where R₁ is a substituted or unsubstituted (C₁-C₁₀) aliphatic chain,
R₂ to R₄ are each independently a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof, and
R₅ is hydrogen, a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof, 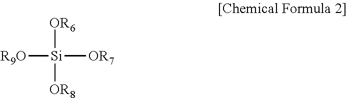
where R₆ to R₉ are each independently a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof, and 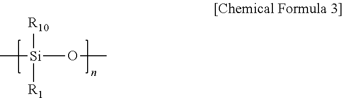
where R₁₀ and R₁₁ are each independently hydrogen, a substituted or unsubstituted (C₁-C₁₀) aliphatic chain, a substituted or unsubstituted (C₁-C₁₀) aliphatic ring, a substituted or unsubstituted (C₆-C₂₀) aromatic ring, or a combination thereof; and
n is an integer of 1 to 2000.

14. The cleaning composition of claim 9, further comprising 0.5 to 1.5 wt % of at least one acid selected from the group consisting of sulfuric acid, nitric acid, hydrochloric acid, hydrofluoric acid, acetic acid, and nitrous acid.

15. The cleaning composition of claim 9, wherein the cleaning composition has a pH of 9 to 12.

16. A cleaning method of an electronic component, the cleaning method comprising:
preparing an electronic component having an active surface on which a connection pad is disposed and an inactive surface opposite to the active surface; and
cleaning a surface of the connection pad of the electronic component,
wherein the cleaning composition of claim 1 is used in the cleaning of the surface of the connection pad of the electronic component.
